(19) United States
(12) Patent Application Publication
(10) Pub. No.: US 2017/0098578 A1
(43) Pub. Date: Apr. 6, 2017

(54) METHOD OF FABRICATING A SEMICONDUCTOR PACKAGE

(71) Applicant: SAMSUNG ELECTRONICS CO., LTD., SUWON-SI (KR)

(72) Inventors: JANGWOO LEE, CHEONAN-SI (KR); YOUNGDOO JUNG, SUWON-SI (KR)

(73) Assignee: SAMSUNG ELECTRONICS CO., LTD., SUWON-SI (KR)

(21) Appl. No.: 15/158,890

(22) Filed: May 19, 2016

(30) Foreign Application Priority Data
Oct. 5, 2015 (KR) 10-2015-0139724

(51) Int. Cl. H01L 21/78; H01L 23/00; H01L 21/02

(52) U.S. Cl. CPC H01L 21/78; H01L 21/02076; H01L 24/81; H01L 24/03; H01L 24/11

(57) ABSTRACT

A method of fabricating a semiconductor package is disclosed. The method includes forming a plurality of semiconductor chips and a mold layer covering the semiconductor chips on a substrate, forming outer terminals on a bottom surface of the substrate, coating a water-soluble material on the bottom surface of the substrate and the outer terminals to form a coating layer, cutting the substrate and the mold layer to separate the semiconductor chips from each other, and forming a shielding layer on the cutted mold layer.

### CROSS-REFERENCE TO RELATED APPLICATIONS

This U.S. non-provisional patent application claims priority under 35 U.S.C. §119 to Korean Patent Application No. 10-2015-0139724, filed on Oct. 5, 2015, in the Korean Intellectual Property Office, the entire contents of which are hereby incorporated by reference.

### BACKGROUND OF THE INVENTION

Example embodiments relate to a semiconductor package, and/or to a method of forming a coating layer covering outer terminals and a method of fabricating a semiconductor package using the same.

As the mobile market expands, research on an electromagnetic wave in electronic devices is being actively conducted. In the case where a plurality of semiconductor packages are mounted on the electronic device, an electromagnetic wave emitted from each semiconductor package may cause electromagnetic interference (EMI) in other semiconductor packages. As a result of the EMI, the electronic device may suffer from several technical failures (e.g., malfunction or operational failures).

In addition, a semiconductor package of package-in-package (PiP) or package-on-package (PoP) type has been developed to meet an increasing demand for high speed and high density semiconductor package, but the EMI remains an unresolved issue in these types of semiconductor packages.

### SUMMARY

Example embodiments of the inventive concepts relate to a method of fabricating a semiconductor package with a shielding layer, and for example to a method capable of substantially preventing a conductive material from being infiltrated into a substrate and outer terminals, when the shielding layer is formed.

According to example embodiments of the inventive concepts, a method of fabricating a semiconductor package may include forming a plurality of semiconductor chips and a mold layer covering the semiconductor chips on a substrate, forming outer terminals on a bottom surface of the substrate, coating a water-soluble material on the bottom surface of the substrate and the outer terminals to form a coating layer, cutting the substrate and the mold layer to separate the plurality of semiconductor chips from each other, and forming a shielding layer on the culled mold layer.

In example embodiments, the water-soluble material may include 2-Butoxyethanol.

In example embodiments, the coating layer may include a water-soluble material that dissolves in water at a temperature of about 50° C. or higher.

In example embodiments, the method may further include performing a cleaning process on the coating layer. The cleaning process may include at least one of a water jet process and a water dipping process.

In example embodiments, the method may further include providing a board on the outer terminals, and connecting the outer terminals to the board.

In example embodiments, the method may further include coating a flux on the outer terminals and connecting the outer terminals to a board. The flux may dissolve the coating layer formed on the outer terminals.

In example embodiments, the method may further include providing a board coated with a flux on the outer terminals and connecting the outer terminals to the board. The flux may dissolve the coating layer formed on the outer terminals.

In example embodiments, after the cutting of the substrate and the mold layer, the shielding layer may be formed to cover top and side surfaces of the cutted mold layer and side surfaces of the culled substrate, and the shielding layer may be electrically connected to a ground pattern provided on the substrate.

According to example embodiments of the inventive concepts, a method of fabricating a semiconductor package may include providing a substrate with connection pads, the substrate having top and bottom surfaces opposite each other, and the connection pads being provided on the bottom surface of the substrate, forming a plurality of semiconductor chips and a mold layer on the substrate, the mold layer covering the plurality of semiconductor chips, forming outer terminals on the connection pads of the substrate, forming a coating layer to cover the outer terminals and the bottom surface of the substrate, cutting the substrate and the mold layer to separate the plurality of semiconductor chips from each other, and forming a shielding layer on at least one of the separated plurality of semiconductor chips.

In example embodiments, the forming of the coating layer may include coating a water-soluble material to cover the bottom surface of the substrate and the outer terminals.

In example embodiments, the forming of the coating layer may include dipping the bottom surface of the substrate and the outer terminals in solution containing a water-soluble material.

In example embodiments, the method may further include performing a cleaning process on the coating layer. The cleaning process may be performed using one of a water jet process and a water dipping process, and at least one of the water jet process and the water dipping process may include supplying water at a temperature of about 50° C. or higher onto the coating layer.

In example embodiments, the coating layer may be formed to cover the bottom surface of the substrate as well as exposed surfaces of the connection pads and the outer terminals.

In example embodiments, the coating layer may be formed of or include a water-soluble material containing 2-Butoxyethanol.

In example embodiments, the method may further include providing a board on the outer terminals and electrically connecting the outer terminals to the board.

According to example embodiments of the inventive concepts, a method of fabricating a semiconductor package may include forming a plurality of semiconductor Chips on a first surface of a substrate, forming a plurality of terminals on a second surface of the substrate opposite the first surface forming a water-soluble coating layer on the plurality of terminals, and forming a mold layer covering the plurality of semiconductor chips

In example embodiments, the water-soluble coating layer may be soluble in water at a temperature of about 50° C. or higher.

In example embodiments, the method may further include removing the water-soluble coating layer prior to mounting the semiconductor package to a board.

In example embodiments, the forming of the plurality of terminals may include forming the plurality of terminals on connection pads that are formed within the second surface of the substrate.

In example embodiments, the method may further include sectioning the semiconductor package to separate the plurality of semiconductor chips from each other, and forming a shielding layer on at least one of the plurality of separated semiconductor chips, the shielding layer covering a top surface and side surfaces of the at least one of the separated plurality of semiconductor chips.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a semiconductor package according to example embodiments of the inventive concepts.

FIGS. 2A to 2E are sectional views illustrating a method of fabricating a semiconductor package, according to example embodiments of the inventive concepts.

FIGS. 3A and 3B are sectional views illustrating a method of connecting a semiconductor package to a board, according to example embodiments of the inventive concepts.

FIGS. 4A and 4B are sectional views illustrating a method of connecting a semiconductor package to a board, according to example embodiments of the inventive concepts.

FIGS. 5A to 5C are sectional views illustrating a method of connecting a semiconductor package to a board, according to example embodiments of the inventive concepts.

It should be noted that these figures are intended to illustrate the general characteristics of methods, structure and/or materials utilized in example embodiments and to supplement the written description provided below. These drawings are not, however, to scale and may not precisely reflect the precise structural or performance characteristics of any given example embodiment, and should not be interpreted as defining or limiting the range of values or properties encompassed by the example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

The inventive concepts will now be described more fully hereinafter with reference to the accompanying drawings, in which example embodiments of the inventive concepts are shown. The inventive concepts and methods of achieving them will be apparent from the following example embodiments that will be described in more detail with reference to the accompanying drawings. The example embodiments of the inventive concepts may, however, be embodied in different forms and should not be constructed as limited to the example embodiments set forth herein. Rather, these embodiments are provided so that this disclosure will be thorough and complete, and will fully convey the scope of the inventive concepts to those skilled in the art.

As used herein, the singular terms “a,” “an” and “the” are intended to include the plural forms as well, unless the context clearly indicates otherwise. It will be understood that when an element is referred to as being “connected” or “coupled” to another element, it may be directly connected or coupled to the other element or intervening elements may be present.

Similarly, it will be understood that when an element such as a layer, region or substrate is referred to as being “on,” “connected” or “coupled” to another element, it can be directly on, directly connected or directly coupled to the other element or intervening elements may be present. In contrast, the term “directly” means that there are no intervening elements. When an element is referred to as being “directly on,” “directly connected” or “directly coupled” to another element, there are no intervening elements present. Further, it will be understood that when a layer is referred to as being “under” another layer, it can be directly under or one or more intervening layers may also be present. In addition, it will also be understood that when a layer is referred to as being “between” two layers, it can be the only layer between the two layers, or one or more intervening layers may also be present. Additionally, the embodiment in the detailed description will be described with sectional views as ideal example views of the inventive concepts. Accordingly, shapes of the example views may be modified according to manufacturing techniques and/or allowable errors. Therefore, the embodiments of the inventive concepts are not limited to the specific shape illustrated in the example views, but may include other shapes that may be created according to manufacturing processes.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

In the drawing figures, the dimensions of layers and regions may be exaggerated for clarity of illustration.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. As used herein, expressions such as “at least one of,” when preceding a list of elements, modify the entire list of elements and do not modify the individual elements of the list.

When the terms “about” or “substantially” are used in this specification in connection with a numerical value, it is intended that the associated numerical value include a tolerance of ±10% around the stated numerical value. Moreover, when reference is made to percentages in this specification, it is intended that those percentages are based on weight, i.e., weight percentages. The expression “up to” includes amounts of zero to the expressed upper limit and all values therebetween. When ranges are specified, the range includes all values therebetween such as increments of 0.1%. Moreover, when the words “generally” and “substantially” are used in connection with geometric shapes, it is intended that precision of the geometric shape is not required but that latitude for the shape is within the scope of the disclosure. Although the tubular elements of the embodiments may be cylindrical, other tubular cross-sectional forms are contemplated, such as square, rectangular, oval, triangular and others.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Example embodiments of the inventive concepts explained and illustrated herein include their complementary counterparts. The same reference numerals or the same reference designators denote the same elements throughout the specification.

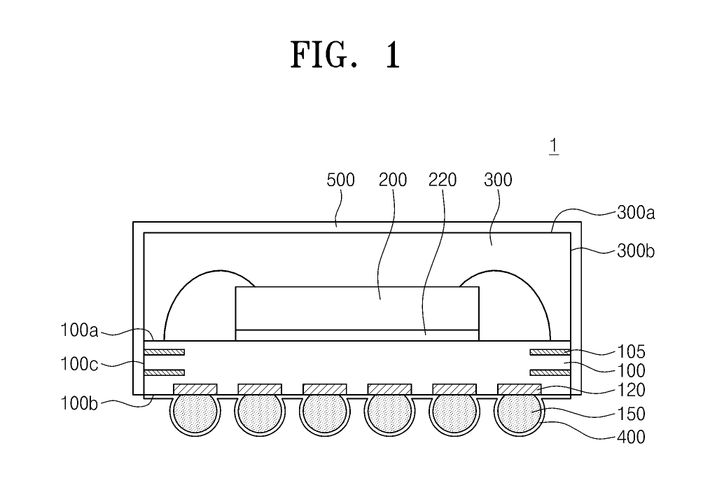

FIG. 1 is a sectional view illustrating a semiconductor package according to example embodiments of the inventive concepts.

Referring to FIG. 1, a semiconductor package 1 may include a substrate 100, a semiconductor chip 200, a mold layer 300, a coating layer 400, and a shielding layer 500.

The substrate 100 may be a printed circuit board (PCB) having top and bottom surfaces 100a and 100b facing each other. The substrate 100 may include a ground pattern 105 exposed through side surfaces 100c. Connection pads 120 may be provided on the bottom surface 100b of the substrate 100, and outer terminals 150 may be provided on the connection pads 120 of the substrate 100. The outer terminals 150 may be electrically connected to the connection pads 120. The outer terminals 150 may be, for example, solder balls. The outer terminals 150 may be formed of or include an alloy including at least one of tin (Sn), silver (Ag), copper (Cu), nickel (Ni), bismuth (Bi), indium (In), antimony (Sb), and cerium (Ce).

The semiconductor chip 200 may be mounted on the top surface 100a of the substrate 100. The semiconductor chip 200 may be coupled to the top surface 100a of the substrate 100 by a wire bonding method. The semiconductor chip 200 may be a logic chip, a memory chip, or any combination thereof. An adhesive layer 220 may be provided between the top surface 100a of the substrate 100 and the semiconductor chip 200.

The mold layer 300 may cover the top surface 100a of the substrate 100 and the semiconductor chip 200. The mold layer 300 may be formed of or include an insulating polymer material epoxy molding compound (EMC)).

The coating layer 400 may be provided to cover the bottom surface 100b of the substrate 100 and the outer terminals 150. The coating layer 400 may be formed of or include at least one of water-soluble materials that can be dissolved in water at a temperature of about 50° C. or higher. For example, the coating layer 400 may include a 2-Butoxyethanol containing material. A molecular formula of 2-Butoxyethanol is C₆H₁₄O₂ and its structural formula is as follows:

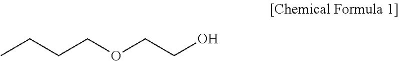

The coating layer 400 may reduce or prevent a short circuit from being formed between the outer terminals 150 and between the outer terminals 150 and the shielding layer 500.

The shielding layer may be provided on the mold layer 300. The shielding layer 500 may be provided to cover top and side surfaces 300a and 300b of the mold layer 300 and the side surfaces 100c of the substrate 100. The shielding layer 500 may be connected to the ground pattern 105 exposed through the side surfaces 100c of the substrate 100. The shielding layer 500 may be formed of or include at least one of, for example, copper (Cu), nickel (Ni), silver (Ag), gold (Au), platinum (Pt), cobalt (Co), titanium (Ti), chromium (Cr), zirconium (Zr), molybdenum (Mo), tungsten (W), ruthenium (Ru), hafnium (Hf), or rhenium (Re).

The shielding layer 500 may reduce or prevent an electromagnetic wave from propagating into or from an electronic device (e.g., mobile devices, computers, and so forth). The shielding layer 500 may be electrically connected to the ground pattern 105 of the substrate 100, and this connection may allow an electromagnetic wave incident thereon to be transmitted to the outside. Furthermore, since the shielding layer 500 may be formed of or include a conductive material, it is possible to better dissipate heat energy generated in the semiconductor package 1 to the outside.

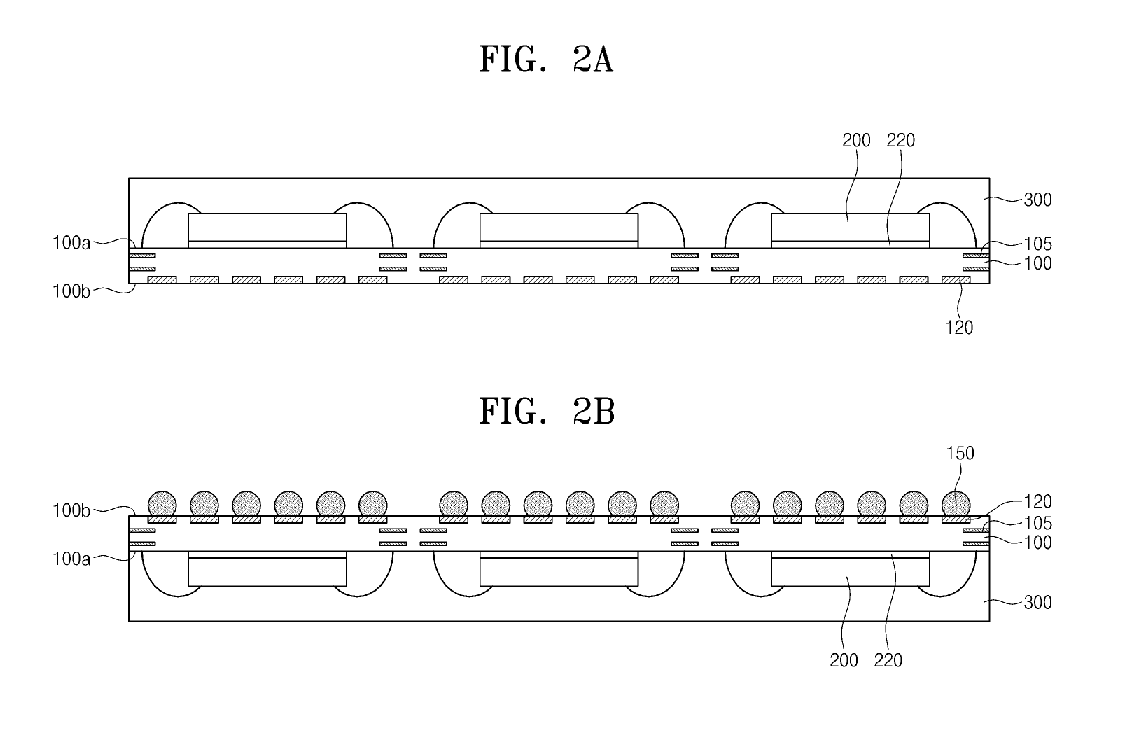

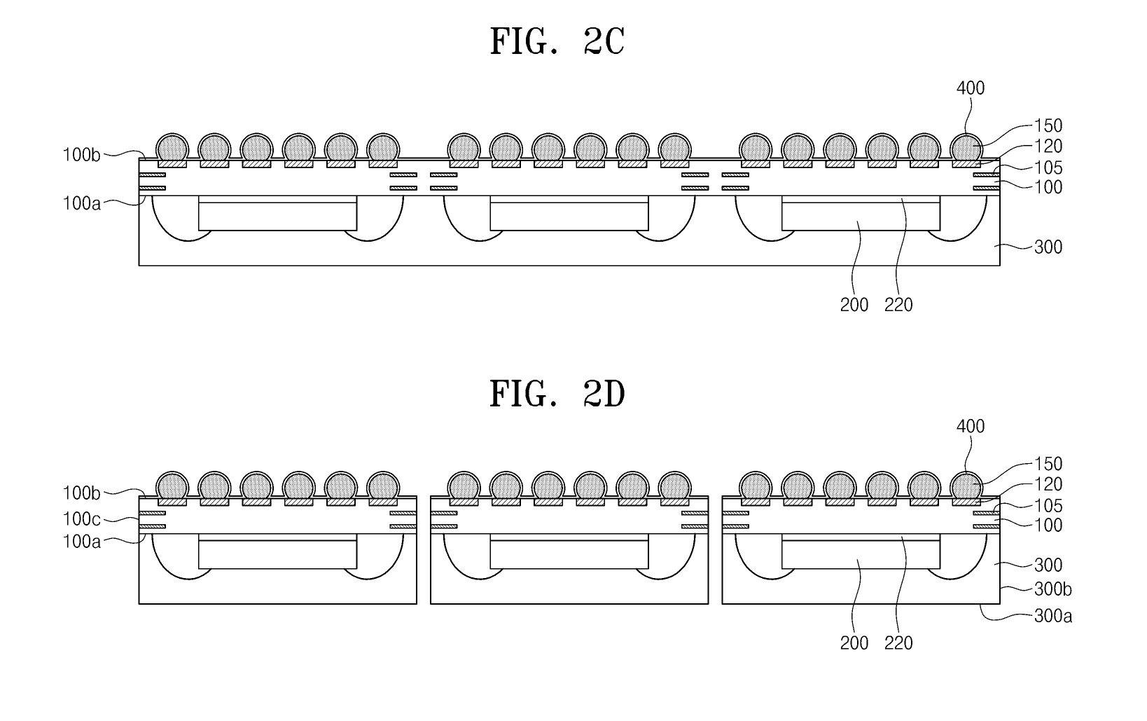

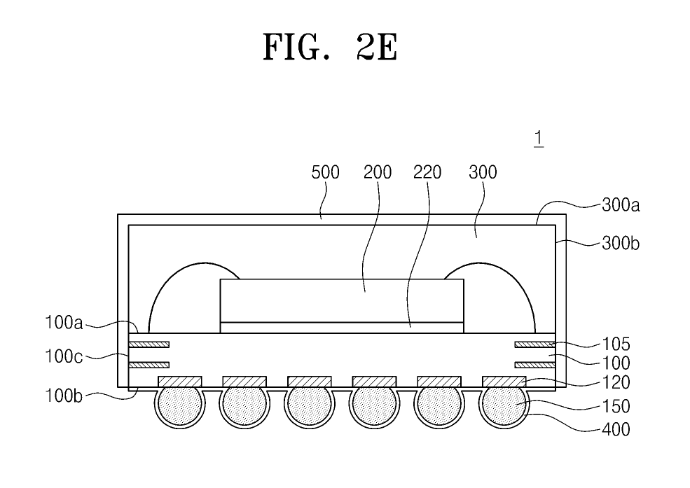

FIGS. 2A to 2E are sectional views illustrating a method of fabricating a semiconductor package, according to example embodiments of the inventive concepts.

Referring to FIG. 2A, semiconductor chips 200 may be mounted on a substrate 100, and a mold layer 300 may be formed to cover the semiconductor chips 200. The substrate 100 may be a strip type structure, on which a plurality of semiconductor chips 200 are provided. The substrate 100 may be a printed circuit board (PCB) that has a top surface 100a and a bottom surface 100b facing each other and includes circuit patterns. The semiconductor chips 200 may be spaced apart fro each other on the top surface 100a, and may be connected to the substrate 100 by a wire bonding method. The adhesive layers 220 may be provided between the top surface 100a of the substrate 100 and the semiconductor chips 200. The mold layer 300 may be formed to cover the top surface 100a of the substrate 100 and the semiconductor chips 200. For example, the mold layer 300 may be formed by a mold under-fill (MUF) process. The mold layer 300 may be formed of or include an insulating polymer material (e.g., epoxy molding compound (EMC)).

Referring to FIG. 2B, outer terminals 150 may be attached to connection pads 120. The outer terminals 150 may be formed of or include an alloy including at least one of tin (Sn), silver (Ag), copper (Cu), nickel (Ni), bismuth (Bi), indium (In), antimony (Sb), and cerium (Ce). The connection pads 120 may be electrically connected to the outer terminals 150.

Referring to FIG. 2C, a coating layer 400 may be formed to cover the bottom surface 100b of the substrate 100, the connection pads 120, and the outer terminals 150. The coating layer 400 may be formed to substantially entirely cover the exposed surfaces of the outer terminals 150. The coating layer 400 may be formed by a method of spraying a water-soluble material or by a method of dipping the bottom surface 100b of the substrate 100 and the outer terminals 150 into solution containing a water-soluble material. The water-soluble material may be dissolved in water at a temperature of about 50° C. or higher. For example, the water-soluble material may contain 2-Butoxyethanol.

Referring to FIG. 2D, a cutting process may be performed on the substrate 100 and the mold layer 300 to separate the semiconductor chips 200 from each other. The cutting process may be performed using a saw blade or laser cutting technique. When the cutting process is finished, the mold layer 300 may have a top surface 300a and side surfaces 300b, and the substrate 100 may have side surfaces 100c exposing a ground pattern 105.

Referring to FIG. 2E, the shielding layer 500 may be formed to cover the mold layer 300 and the side surfaces 100c of the substrate 100. The shielding layer 500 may be formed to cover top and side surfaces 300a and 300b of the mold layer 300 and the side surfaces 100c of the substrate 100. The shielding layer 500 may be formed by a sputtering process, an electroplating process, or an electroless plating process. The shielding layer 500 may be formed of or include at least one conductive material such as, copper (Cu), nickel (Ni), silver (Ag), gold (Au), platinum (Pt), cobalt (Co), titanium (Ti), chromium (Cr), zirconium (Zr), molybdenum (Mo), tungsten (W), ruthenium (Ru), hafnium (Hf), or rhenium (Re). As a result, the semiconductor package 1 with the shielding layer 500 may be fabricated.

During the formation of the shielding layer 500, a conductive material of the shielding layer 500 may be infiltrated into the outer terminals 150 provided on the bottom surface 100b of the substrate 100, thereby causing occurrence of a short circuit therebetween. According to example embodiments of the inventive concepts, the coating layer 400 may be formed to cover the bottom surface 100b of the substrate 100 and the outer terminals 150, thereby substantially preventing the conductive material from being infiltrated into the bottom surface 100b of the substrate 100 and the outer terminals 150. Accordingly, when the coating layer 400 is formed, it is possible to substantially prevent a short circuit from being formed between the shielding layer 500 and the outer terminals 150, without any additional process for protecting the outer terminals 150. In addition, since the coating layer 400 is formed of or include a water-soluble material, the coating layer 400 can be easily removed.

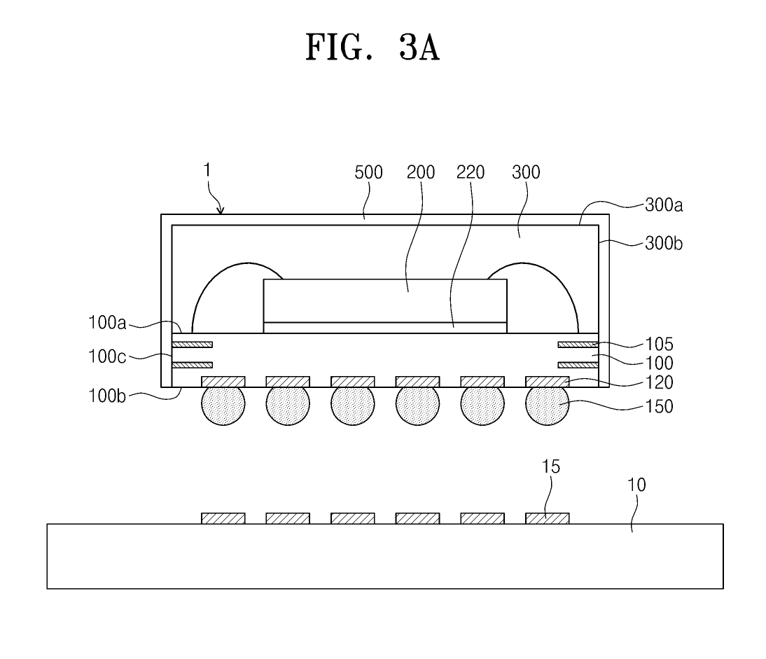

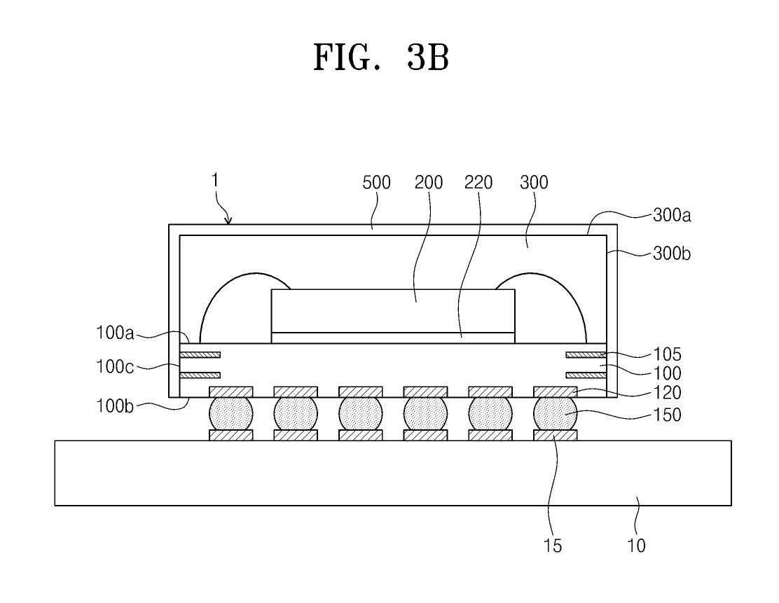

FIGS. 3A and 3B are sectional views illustrating a method of connecting a semiconductor package to a board, according to example embodiments of the inventive concepts. FIGS. 3A and 3B are sectional views illustrating subsequent steps, which may be performed after the process steps described with reference to FIGS. 2A to 2E.

Referring to FIG. 3A, a cleaning process may be performed on the coating layer 400, which is formed on the bottom surface 100b of the substrate 100 and the outer terminals 150. The cleaning process of the coating layer 400 may include a water jet process and a water dipping process. For example, water at a temperature of about 50° C. or higher may be supplied on the coating layer 400, and in this case, the coating layer 400 may be removed via a hydrolysis reaction with the water.

Referring to FIGS. 3A and 3B, the semiconductor package 1 may be mounted on a board 10. For example, the board 10 may be a board for a mobile device (e.g., a cellular phone) or a memory module. The outer terminals 150 of the semiconductor package 1 may be electrically connected to outer pads 15 provided on the board 10.

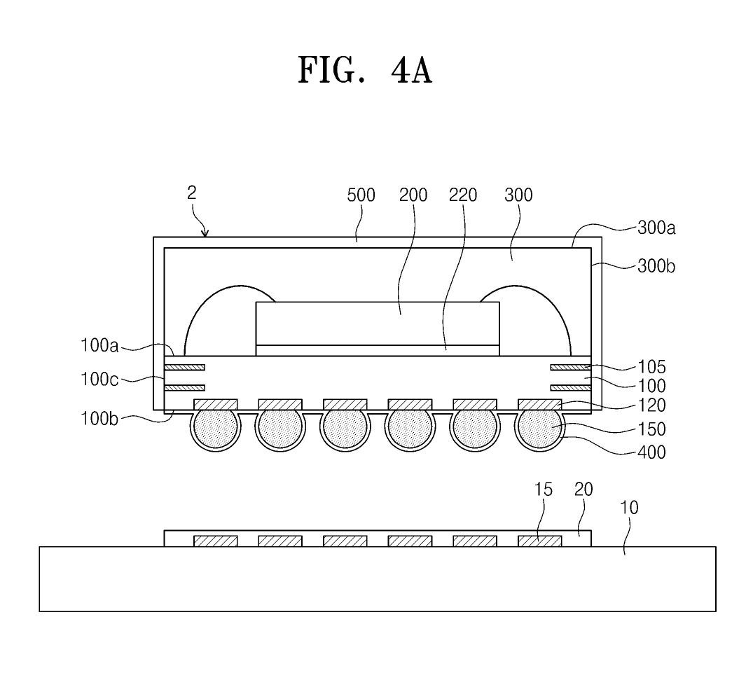

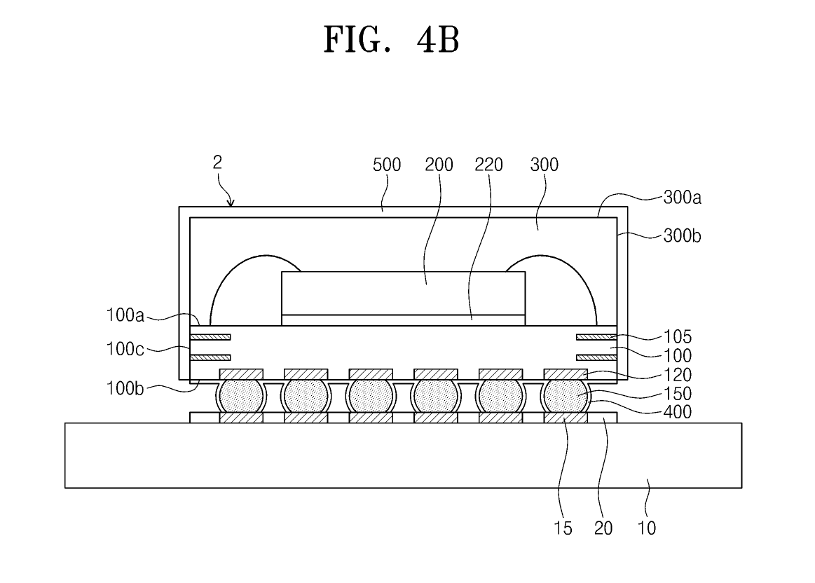

FIGS. 4A and 4B are sectional views illustrating a method of connecting a semiconductor package to a board, according to example embodiments of the inventive concepts. FIGS. 4A and 4B are sectional views illustrating subsequent steps, which may be performed after the process steps described with reference to FIGS. 2A to 2E.

Referring to FIG. 4A, a semiconductor package 2 may include the outer terminals 150, and the board 10 may be provided on the outer terminals 150 of the semiconductor package 2. For example, the board 10 may be aboard for a mobile device (e.g., a cellular phone) or a memory module. The outer pads 15 may be provided on the board 10, and a flux 20 may be coated on the outer pads 15. The flux 20 may be provided on the outer pads 15 by a screen printing process or a dipping process. For example, the flux 20 may include a resin, an activator, and a solvent. The resin may serve as a base material of the flux 20, and the use of the resin may make it possible to remove an oxide layer from metallic surfaces of the outer terminals 150, to reduce a surface tension in a soldering process, to decrease a melting point of the outer terminals 150, and to substantially prevent an oxide layer from being subsequently formed on the metallic surface. The activator may include at least one of carboxylic acid, sulfonic acid, phosphonic acid, amino acid, and alkanol amine. The activator may substantially prevent a soldering process from suffering from the resin having poor wetting or fluidic characteristics. In addition, the presence of the activator may allow the flux 20 to remove an oxide layer from the metallic surfaces of the outer terminals 150. The solvent may include at least one of glycol ether ester compounds, glycol ether compounds, ester compounds, ketone compounds, and cyclic ester compounds. The presence of the solvent may contribute to improve a wetting property of the solder.

Referring to FIG. 48, the semiconductor package 2 may be mounted on the board 10. The coating layer 400 on the outer terminals 150 may be dissolved by the flux 20 provided on the board 10. The coating layer 400 may be formed of or include a 2-Butoxyethanol-containing material, and in this case, since the 2-Butoxyethanol is polar, the coating layer 400 may be dissolved by a polar solvent. The polar solvent may include at least one of for example, water, ethanol, and acid. Since the flux 20 may be an acid-containing material, the coating layer 400 may be dissolved by the flux 20. As a result, the outer terminals 150 may be in direct contact with the outer pads 15 provided on the board 10, such that the outer terminals 150 may be electrically connected to the outer pads 15.

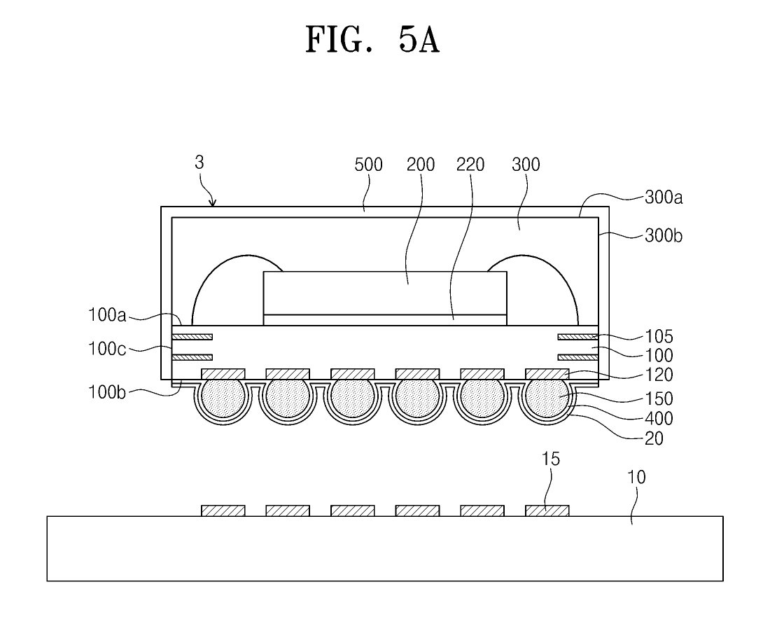

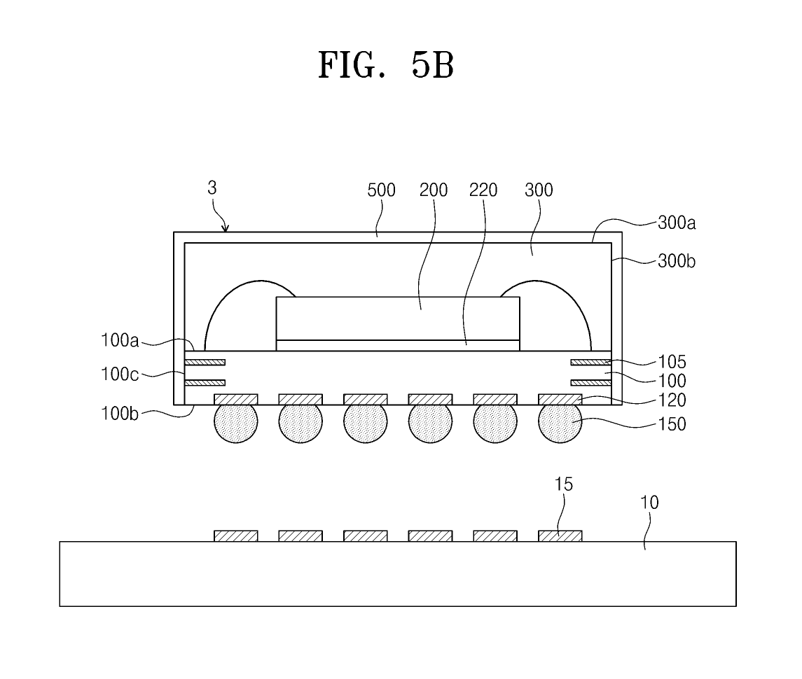

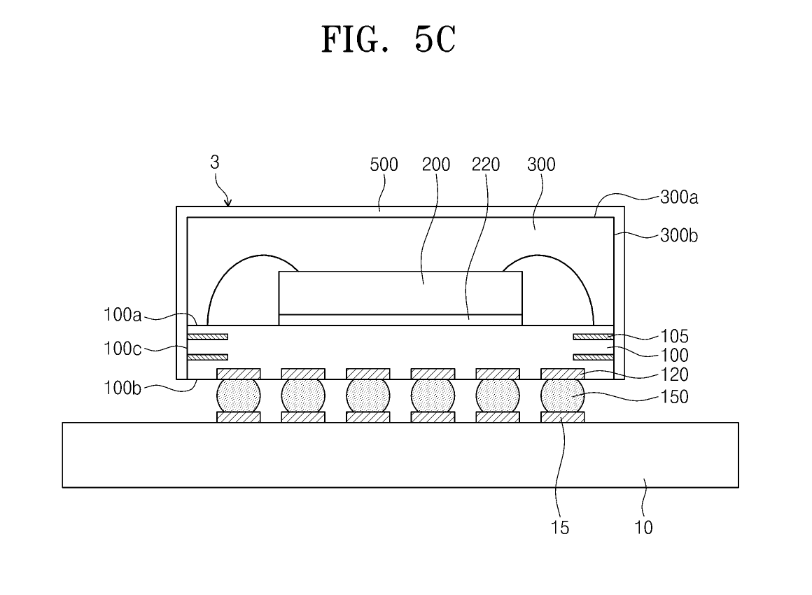

FIGS. 5A to 5C are sectional views illustrating a method of connecting a semiconductor package to a board, according to example embodiments of the inventive concepts. FIGS. 5A to 5C are sectional views illustrating subsequent steps, which may be performed after the process steps described with reference to FIGS. 2A to 2E.

Referring to FIG. 5A, a semiconductor package 3 may include the coating layer 400, and the flux 20 may be coated on the coating layer 400. The flux 20 may be provided on the coating layer 400 by a screen printing process or a dipping process. The board 10 provided with the outer pads 15 may be provided below a bottom surface of the semiconductor package 3.

Referring to FIG. 5B, the coating layer 400 provided on the outer terminals 150 may be dissolved by the flux 20. In detail, the coating layer 400 may be formed of or include a 2-Butoxyethanol-containing material, and in this case, since the 2-Butoxyethanol is polar, the coating layer 400 may be dissolved by a polar solvent. The polar solvent may include at least one of, for example, water, ethanol, and acid. Since the flux 20 may be an acid-containing material, the coating layer 400 may be dissolved by the flux 20.

Referring to FIG. 5C, the semiconductor package 3 may be mounted on the board 10. For example, the board 10 may be a board for a mobile device (e.g., a cellular phone) or a memory module. The coating layer 400 may be removed to expose the outer terminals 150, and the outer terminals 150 may be in direct contact with and electrically connected to the outer pads 15 provided on the board 10.

In example embodiments, the semiconductor chips 200 may be mounted on the substrate 100 in various other manners. For example, the semiconductor chips 200 and the substrate 100 may be electrically connected to each other in a flip-chip bonding manner, and in this case, bumps may be used instead of an adhesive tape. Alternatively, in the case where a semiconductor package includes a plurality of vertically-stacked semiconductor chips 200, through-silicon-vias (TSVs) may be provided in the semiconductor chips 200 to electrically connect the semiconductor chips 200 to each other or the substrate 100.

According to example embodiments of the inventive concepts, it is possible to substantially prevent a conductive material from being infiltrated into a substrate and outer terminals, when a shielding layer is formed.

According to example embodiments of the inventive concepts, it is possible to remove a coating layer by a cleaning process using water, and consequently to simplify a process of fabricating a semiconductor package.

According to example embodiments of the inventive concepts, it is possible to remove a coating layer using a flux, which may be supplied when a semiconductor package is mounted on a board, and consequently to omit an additional process for removing the coating layer.

While example embodiments of the inventive concepts have been particularly shown and described, it will be understood by one of ordinary skill in the art that variations in form and detail may be made therein without departing from the spirit and scope of the attached claims.

What is claimed is:

1. A method of fabricating a semiconductor package, comprising:
forming a plurality of semiconductor chips and a mold layer covering the semiconductor chips, on a substrate;
forming outer terminals on a bottom surface of the substrate;
coating a water-soluble material on the bottom surface of the substrate and the outer terminals to form a coating layer;
cutting the substrate and the mold layer to separate the plurality of semiconductor chips from each other; and
forming a shielding layer on the culled mold layer.

2. The method of claim 1, wherein the water-soluble material includes 2-Butoxyethanol.

3. The method of claim 1, wherein the coating layer includes a water-soluble material that is soluble by water at a temperature of about 50° C. or higher.

4. The method of claim 1, further comprising:
performing a cleaning process on the coating layer, wherein the cleaning process includes at least one of a water jet process and a water dipping process.

5. The method of claim 4, further comprising:
providing a board on the outer terminals and
connecting the outer terminals to the board.

6. The method of claim 1, further comprising:
coating a flux on the outer terminals; and
connecting the outer terminals to a board,
wherein the dissolves the coating layer formed on the outer terminals.

7. The method of claim 1, further comprising:
providing a board coated with a flux on the outer terminals; and
connecting the outer terminals to the board,
wherein the flux dissolves the coating layer formed on the outer terminals.

8. The method of claim 1, wherein, after the cutting of the substrate and the mold layer, the shielding layer is formed to cover top and side surfaces of the cutted mold layer and a side surfaces of the cutted substrate, and
the shielding layer is electrically connected to a ground pattern provided on the substrate.

9. A method of fabricating a semiconductor package, comprising:
providing a substrate with connection pads, the substrate having top and bottom surfaces opposite each other, and the connection pads being provided on the bottom surface of the substrate;
forming a plurality of semiconductor chips and a mold layer on the substrate, the mold layer covering the plurality of semiconductor chips;
forming outer terminals on the connection pads of the substrate;
forming a coating layer to cover the outer terminals and the bottom surface of the substrate;
cutting the substrate and the mold layer to separate the plurality of semiconductor chips from each other, and
forming a shielding layer on at least one of the separated plurality of semiconductor chips.

10. The method of claim 9, wherein the forming of the coating layer comprises coating a water-soluble material to cover the bottom surface of the substrate and the outer terminals.

11. The method of claim 9, wherein the forming of the coating layer comprises dipping the bottom surface of the substrate and the outer terminals in a solution containing a water-soluble material.

12. The method of claim 9, further comprising:
performing a cleaning process on the coating layer,
wherein the cleaning process is performed using one of a water jet process and a water dipping process, and
at least one of the water jet process and the water dipping process includes supplying water at a temperature of about 50° C. or higher onto the coating layer.

13. The method of claim 9, wherein the coating layer is formed to cover the bottom surface of the substrate and exposed surfaces of the connection pads and the outer terminals.

14. The method of claim 9, wherein the coating layer includes a water-soluble material including 2-Butoxyethanol.

15. The method of claim 9, further comprising:
providing a board on the outer terminals; and
electrically connecting the outer terminals to the board.

16. A method of manufacturing a semiconductor package, comprising:
forming a plurality of semiconductor chips on a first surface of a substrate;
forming a plurality of terminals on a second surface of the substrate opposite the first surface;
forming a water-soluble coating layer on the plurality of terminals; and
forming a mold layer covering the plurality of semiconductor chips.

17. The method of claim 16, wherein the water-soluble coating layer is soluble in water at a temperature of about 50° C. or higher.

18. The method of claim 16, further comprising:
removing the water-soluble coating layer prior to mounting the semiconductor package to a board.

19. The method of claim 16, wherein the forming of the plurality of terminals includes
forming the plurality of terminals on connection pads that are formed within the second surface of the substrate.

20. The method of claim 16, further comprising:
sectioning the semiconductor package to separate the plurality of semiconductor chips from each other; and
forming a shielding layer on at least one of the plurality of separated semiconductor chips, the shielding layer covering a top surface and side surfaces of the at least one of the separated plurality of semiconductor chips.
